(19) United States
(12) Patent Application Publication
(10) Pub. No.: US 2025/0338723 A1
(43) Pub. Date: Oct. 30, 2025

(54) DISPLAY DEVICE

(71) Applicant: Japan Display Inc., Tokyo (JP)

(72) Inventors: Yozo NAKAYASU, Tokyo (JP); Sho YANAGISAWA, Tokyo (JP); Kazuyuki HARADA, Tokyo (JP); Tomokazu ISHIKAWA, Tokyo (JP)

(73) Assignee: Japan Display Inc., Tokyo (JP)

(21) Appl. No.: 19/093,257

(22) Filed: Mar. 28, 2025

(30) Foreign Application Priority Data
Apr. 25, 2024 (JP) 2024-071334

(51) Int. Cl. H10K 59/122; H10K 59/80; H10K 59/88

(52) U.S. Cl. CPC H10K 59/122; H10K 59/873; H10K 59/88

(57) ABSTRACT

According to one embodiment, a display device includes a display area including pixels, display elements including an organic layer, a dummy pixel area which includes a plurality of dummy pixels and is located outside the display area, and a partition which includes a conductive lower portion and an upper portion having an end portion protruding from a side surface of the lower portion and surrounds each of the pixels and the dummy pixels. The partition has an outer circumferential portion located outside the dummy pixel area, and is divided into a plurality of segments by a slit which passes through the display area and the dummy pixel area and which reaches the outer circumferential portion.

### CROSS-REFERENCE TO RELATED APPLICATION

This application is based upon and claims the benefit of priority from Japanese Patent Application No. 2024-071334, filed Apr. 25, 2024, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In this type of display devices, a technique for improving the yield is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is the schematic cross-sectional view of the display device along the III-III line of FIG. 2.

FIG. 4 is a schematic plan view showing some elements of the display device.

FIG. 5 is a schematic plan view showing an example of a configuration which can be applied to a partition according to the first embodiment.

FIG. 6 is a schematic plan view showing an example of the relationship between sealing layers and a slit according to the first embodiment.

FIG. 7 is the schematic cross-sectional view of the display device along the VII-VII line of FIG. 6.

FIG. 8 is a flowchart showing an example of the manufacturing method of the display device.

FIG. 9A is a schematic cross-sectional view showing the manufacturing process of the display device.

FIG. 9B is a schematic cross-sectional view showing a process following FIG. 9A.

FIG. 9C is a schematic cross-sectional view showing a process following FIG. 9B.

FIG. 9D is a schematic cross-sectional view showing a process following FIG. 9C.

FIG. 9E is a schematic cross-sectional view showing a process following FIG. 9D.

FIG. 9F is a schematic cross-sectional view showing a process following FIG. 9E.

FIG. 9G is a schematic cross-sectional view showing a process following FIG. 9F.

FIG. 9H is a schematic cross-sectional view showing a process following FIG. 9G.

FIG. 9I is a schematic cross-sectional view showing a process following FIG. 9H.

FIG. 9J is a schematic cross-sectional view showing a process following FIG. 9I.

FIG. 10 is a diagram for explaining the effect of the display device according to the first embodiment.

FIG. 11 is a diagram for explaining the effect of the display device according to the first embodiment.

FIG. 12 is a schematic cross-sectional view of a configuration according to a comparative example of the first embodiment.

FIG. 13 is a schematic plan view of the partition according to a comparative example of the first embodiment.

FIG. 14 is a schematic plan view showing a configuration according to a second embodiment.

FIG. 15 is a schematic plan view showing a configuration according to a third embodiment.

FIG. 16 is a schematic plan view showing a configuration according to a fourth embodiment.

FIG. 17 is a schematic plan view showing a configuration according to a fifth embodiment.

FIG. 18 is the schematic cross-sectional view of the display device along the XVIII-XVIII line of FIG. 17.

FIG. 19 is a schematic plan view showing a configuration according to a sixth embodiment.

FIG. 20 is a schematic plan view showing a configuration according to a seventh embodiment.

### DETAILED DESCRIPTION

In general, according to one embodiment, a display device comprises a display area which includes a plurality of pixels, a plurality of display elements which are provided in the pixels, respectively, and each of which includes an organic layer which emits light based on application of voltage, a dummy pixel area which includes a plurality of dummy pixels and is located outside the display area, and a partition which includes a conductive lower portion and an upper portion having an end portion protruding from a side surface of the lower portion and surrounds each of the pixels and the dummy pixels. The partition has an outer circumferential portion located outside the dummy pixel area, and is divided into a plurality of segments by a slit which passes through the display area and the dummy pixel area and which reaches the outer circumferential portion.

According to another aspect of the embodiment, a display device comprises a display area which includes a plurality of pixels, a plurality of display elements which are provided in the pixels, respectively, and each of which includes an organic layer which emits light based on application of voltage, and a partition which includes a conductive lower portion and an upper portion having an end portion protruding from a side surface of the lower portion, and surrounds each of the pixels. The partition has an outer circumferential portion located outside the display area, and is divided into a plurality of segments by a slit which passes through the display area and which reaches the outer circumferential portion. The slit has a first width in the display area, and has a second width greater than the first width in at least part of the outer circumferential portion.

These configurations can provide a display device such that the yield can be improved.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

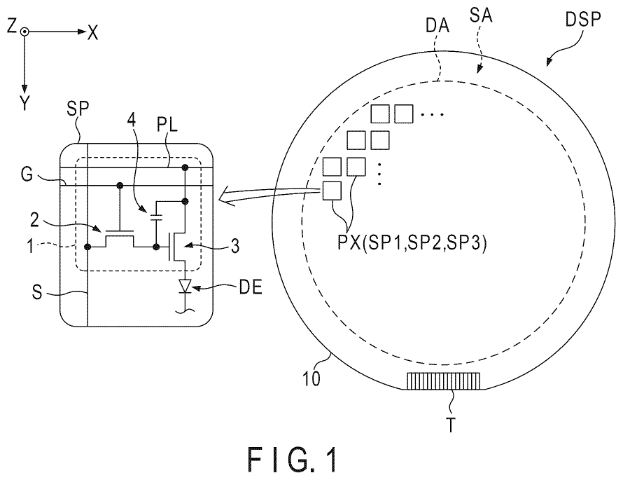

FIG. 1 is a diagram showing a configuration example of a display device DSP according to a first embodiment. The display device DSP comprises an insulating substrate 10. The substrate 10 has a display area DA which displays images, and a surrounding area SA located around the display area DA. The substrate 10 may be glass or a resinous film having flexibility.

In the embodiment, the substrate 10 and the display area DA are circular as seen in plan view. It should be noted that the shape of the substrate 10 or the display area DA in plan view is not limited to a circle and may be another shape such as a rectangle, a square or an oval.

The display area DA comprises a plurality of pixels PX arrayed in matrix in an X-direction and a Y-direction. Each pixel includes a plurality of subpixels SP which display different colors. This embodiment assumes a case where each pixel PX includes a blue subpixel (first subpixel) SP1, a green subpixel (second subpixel) SP2 and a red subpixel (third subpixel) SP3. Each pixel PX may include a subpixel SP which exhibits another color such as white in addition to subpixels SP1, SP2 and SP3 or instead of one of subpixels SP1, SP2 and SP3.

The display device DSP further comprises a terminal portion T provided in the surrounding area SA. For example, a flexible printed circuit which applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

In the display area DA, a plurality of scanning lines G which supply scanning signals to the pixel circuit 1 of each subpixel SP, a plurality of signal lines S which supply video signals to the pixel circuit 1 of each subpixel SP and a plurality of power lines PL are provided. In the example of FIG. 1, the scanning lines G and the power lines PL extend in the X-direction, and the signal lines S extend in the Y-direction.

The gate electrode of the pixel switch 2 is connected to the scanning line G. One of the source electrode and drain electrode of the pixel switch 2 is connected to the signal line S. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

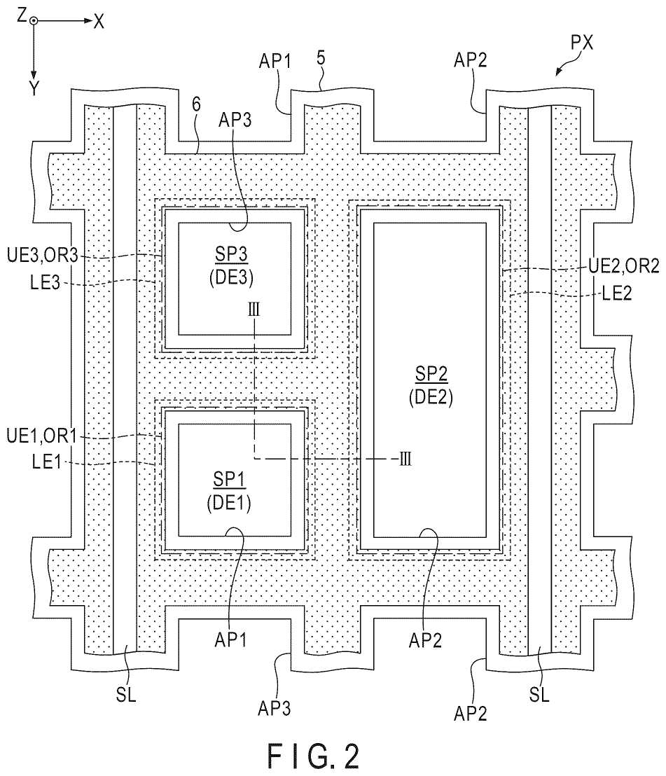

FIG. 2 is a schematic plan view showing an example of the layout of subpixels SP1, SP2 and SP3 constituting a pixel PX. In the example of FIG. 2, subpixels SP1 and SP3 are arranged in the Y-direction. Each of subpixels SP1 and SP3 is adjacent to subpixel SP2 in the X-direction.

When subpixels SP1, SP2 and SP3 are provided in line with this layout, a column in which subpixels SP1 and SP3 are alternately provided in the Y-direction and a column in which a plurality of subpixels SP2 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP1, AP2 and AP3 in subpixels SP1, SP2 and SP3, respectively. In the example of FIG. 2, the pixel apertures AP1 and AP3 are rectangles whose areas are equal to each other. The pixel aperture AP2 is a rectangle which is elongated in the Y-direction relative to the pixel apertures AP1 and AP3. It should be noted that the shape of the pixel aperture AP1, AP2 or AP3 is not limited to this example.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element (first display element) DE1 of subpixel SP1. Of the lower electrode LE2, the upper electrode UE2 and the organic layer OR2, the portions which overlap the pixel aperture AP2 constitute the display element (second display element) DE2 of subpixel SP2. Of the lower electrode LE3, the upper electrode UE3 and the organic layer OR3, the portions which overlap the pixel aperture AP3 constitute the display element (third display element) DE3 of subpixel SP3. Each of the display elements DE1, DE2 and DE3 may further include a cap layer as described later. The rib layer 5 surrounds each of these display elements DE1, DE2 and DE3.

A conductive partition 6 is provided above the rib layer 5. The partition 6 functions as lines which apply common voltage to the upper electrodes UE1, UE2 and UE3. The partition 6 overlaps the rib layer 5 as a whole and has a planar shape similar to that of the rib layer 5. The partition 6 surrounds each of the pixels PX provided in the display area DA. More specifically, the partition 6 surrounds each of subpixels SP1, SP2 and SP3.

As described in detail later, the partition 6 has a plurality of slits SL. In the example of FIG. 2, each slit SL extends in the Y-direction. For example, subpixels SP1, SP2 and SP3 constituting one pixel PX are provided between two slits SL which are adjacent to each other in the X-direction.

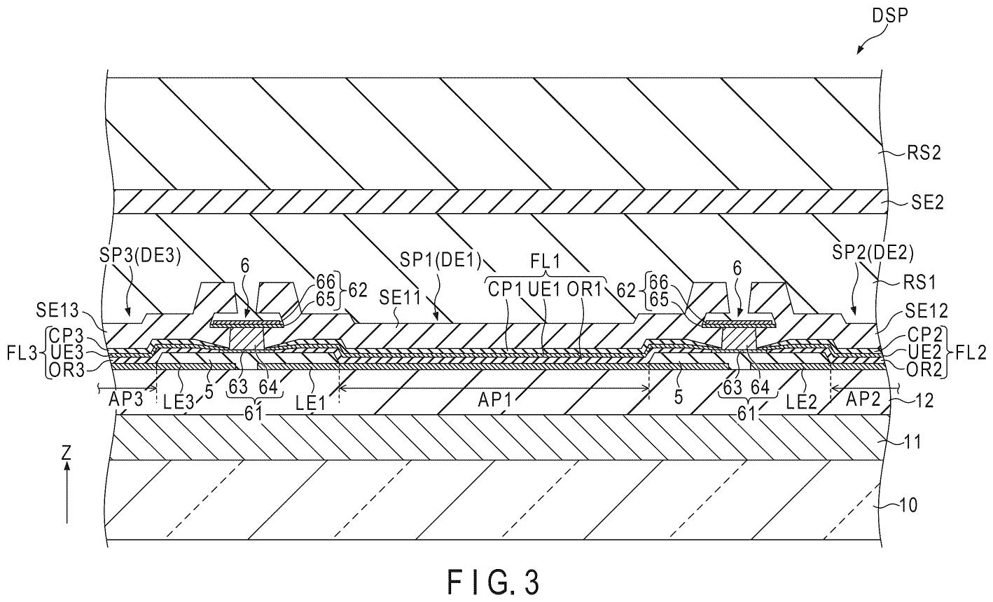

FIG. 3 is the schematic cross-sectional view of the display device DSP along the III-III line of FIG. 2. A circuit layer 11 is provided on the substrate 10 described above. The circuit layer 11 includes various circuits and lines such as the pixel circuits 1, scanning lines G, signal lines S and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

In the example of FIG. 3, the upper portion 62 comprises a first top layer 65, and a second top layer 66 provided on the first top layer 65. For example, the width of the second top layer 66 is slightly less than that of the first top layer 65. It should be noted that the configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the lower portions 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

Sealing layers (first to third sealing layers) SE11, SE12 and SE13 are provided in subpixels SP1, SP2 and SP3, respectively. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 3, the sealing layer SE11 located on the partition 6 between subpixels SP1 and SP2 is spaced apart from the sealing layer SE12 located on this partition 6. The sealing layer SE11 located on the partition 6 between subpixels SP1 and SP3 is spaced apart from the sealing layer SE13 located on this partition 6. It should be noted that two of the sealing layers SE11, SE12 and SE13 may be in contact with each other above the partition 6.

For example, a gap is formed between each of the sealing layers SE11, SE12 and SE13 and the upper portion 62 of the partition 6. The stacked films FL1, FL2 and FL3 may be provided in at least part of these gaps.

The sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend to the surrounding area SA.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA). The electrodes which constitute the touch panel described above may be provided on the sealing layer SE2.

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6 is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

The first top layer 65 of the partition 6 is formed of, for example, a metal material. The second top layer 66 of the partition 6 is formed of, for example, a conductive oxide. For the metal material forming the first top layer 65, for example, titanium, titanium nitride, molybdenum, tungsten, a molybdenum-tungsten alloy or a molybdenum-niobium alloy can be used. For the conductive oxide forming the second top layer 66, for example, ITO or IZO can be used. It should be noted that the upper portion 62 may comprise three or more layers or may consist of a single layer. The upper portion 62 may further include a layer formed of an insulating material.

Common voltage is applied to the partition 6. This common voltage is applied to each of the upper electrodes UE1, UE2 and UE3 which are in contact with the lower portions 61. Pixel voltage is applied to the lower electrodes LE1, LE2 and LE3 through the pixel circuits 1 provided in subpixels SP1, SP2 and SP3, respectively, based on the video signals of the signal lines S.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

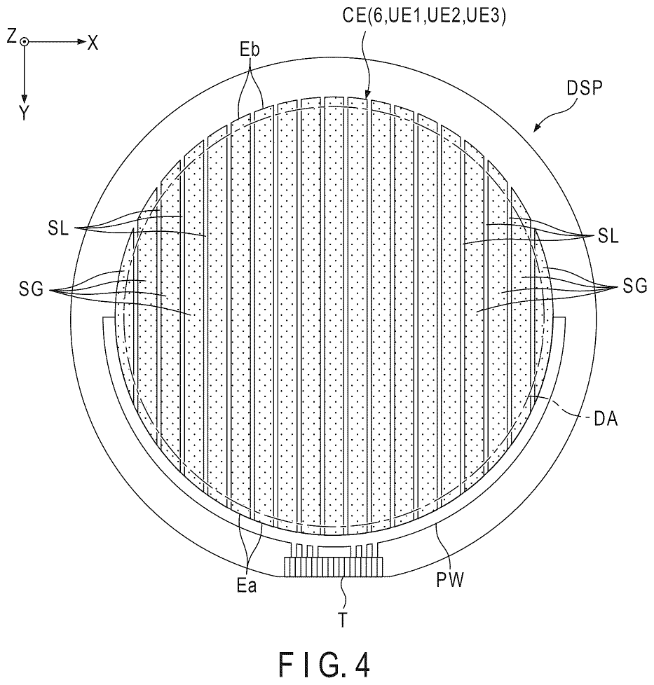

FIG. 4 is a schematic plan view showing some elements of the display device DSP. The partition 6 and the upper electrodes UE1, UE2 and UE3 constitute a common electrode CE which applies common voltage to the display elements DE1, DE2 and DE3. The common electrode CE is, for example, circular, and overlaps the display area DA as a whole.

The common electrode CE has a plurality of slits SL. At least one end of each of the slits SL reaches the outer edge of the common electrode CE (the outline in plan view). In the example of FIG. 4, both ends of each slit SL reach the outer edge of the common electrode CE. By this configuration, the common electrode CE is divided into a plurality of segments SG which are spaced apart from each other via the slits SL.

In the example of FIG. 4, each slit SL extends in the Y-direction. As another example, each slit SL may extend parallel to the X-direction. The number of slits SL provided in the common electrode CE is not particularly limited. For example, at least 17 slits SL are provided, thereby dividing the common electrode CE into at least 18 segments.

The interval of the slits SL in the X-direction is, for example, constant. In this case, the widths of the segments SG in the X-direction are also constant. As another example, the interval of the slits SL or the widths of the segments SG may not be constant.

Each segment SG has a first end portion Ea and a second end portion Eb in the extension direction of the slits SL (in this embodiment, the Y-direction). Each first end portion Ea is connected to a power supply line PW provided in the surrounding area SA. The power supply line PW is connected to the terminal portion T. Common voltage is applied to each segment SG from the terminal portion T via the power supply line PW. In the example of FIG. 4, the second end portions Eb of the segments SG are spaced apart from each other via the slits SL and are not connected by a conductive member such as the power supply line PW.

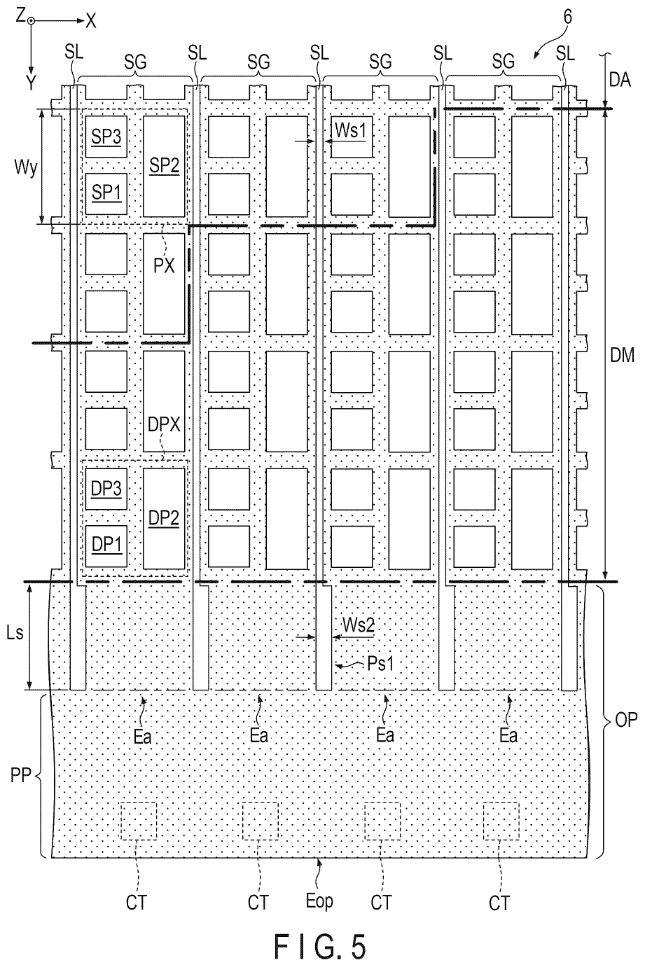

FIG. 5 is a schematic plan view showing an example of a configuration which can be applied to the partition 6 according to the embodiment. In this figure, the vicinity of the first end portion Ea of each segment SG is particularly looked at.

In this embodiment, a dummy pixel area DM is provided outside the display area DA. The dummy pixel area DM is part of the surrounding area SA described above. The dummy pixel area DM includes a plurality of dummy pixels DPX and surrounds the display area DA. From another viewpoint, the dummy pixels DPX are provided so as to surround the pixels PX provided in the display area DA.

For example, each dummy pixel DPX includes dummy subpixels DP1, DP2 and DP3. Dummy subpixels DP1, DP2 and DP3 have structures similar to those of subpixels SP1, SP2 and SP3, respectively. However, dummy subpixels DP1, DP2 and DP3 are configured not to emit light. This configuration may be realized by, for example, disconnecting part of the pixel circuit 1 in each of dummy subpixels DP1, DP2 and DP3. The pixel apertures AP1, AP2 and AP3 may be omitted in dummy subpixels DP1, DP2 and DP3, respectively.

Part of the partition 6 is located in the dummy pixel area DM and surrounds each of dummy subpixels DPX. More specifically, the partition 6 surrounds each of dummy subpixels DP1, DP2 and DP3. The shape and layout of the aperture of the partition 6 in each of dummy subpixels DP1, DP2 and DP3 are similar to those of the aperture of the partition 6 in a corresponding subpixel SP1, SP2 or SP3.

In the example of FIG. 5, the partition 6 further includes an outer circumferential portion OP located outside the dummy pixel area DM. For example, the outer circumferential portion OP does not have an aperture such as the apertures of dummy subpixels DP1, DP2 and DP3. It should be noted that apertures having shapes different from those of the apertures of dummy subpixels DP1, DP2 and DP3 may be provided in the outer circumferential portion OP. The outer circumferential portion OP is connected to the power supply line PW shown in FIG. 4 via a plurality of contact portions CT.

For example, the outer circumferential portion OP surrounds the display area DA and the dummy pixel area DM. As another example, the outer circumferential portion OP may be provided in part of the surrounding area of the display area DA and the dummy pixel area DM.

The slits SL are provided in portions extending parallel to the Y-direction in the partition 6. Specifically, in the example of FIG. 5, each slit SL is provided in the portion located between pixels PX which are adjacent to each other in the X-direction in the partition 6. However, the form of the slits SL is not limited to this example. For example, two or more pixels PX may be arranged between adjacent slits SL in the X-direction.

An end portion of each slit SL is located in the outer circumferential portion OP. In other words, each slit SL passes through the display area DA and the dummy pixel area DM and reaches the outer circumferential portion OP.

In the example of FIG. 5, the end portion of each slit SL does not reach the outer edge EoP of the outer circumferential portion OP. By this configuration, a continuous portion PP which is not divided by the slits SL is formed between the end portion of each slit SL and the outer edge EoP. The continuous portion PP connects the first end portions Ea of the segments SG to each other. The contact portions CT are located in the continuous portion PP.

The second end portions Eb of the segments SG shown in FIG. 4 are not connected to each other by the continuous portion PP or the like. In other words, each second end portion Eb reaches the outer edge EoP of the outer circumferential portion OP.

Each pixel PX has width Wy in the Y-direction (the extension direction of the slits SL). The width of each dummy pixel DPX in the Y-direction is, for example, equal to width Wy. Width Wy corresponds to the pitch of the pixels PX arranged in the Y-direction. For example, length Ls of each slit SL in the outer circumferential portion OP is greater than or equal to width Wy (Ls≥Wy).

Each slit SL has width Ws1 (first width) in the display area DA. Further, each slit SL has width Ws2 (second width) in at least part of the outer circumferential portion OP. Width Ws2 is greater than width Ws1 (Ws2>Ws1).

From another viewpoint, each slit SL has a wide portion Ps1 located in the outer circumferential portion OP. In the example of FIG. 5, each slit SL located in the outer circumferential portion OP consists of the wide portion Ps1 as a whole. As another example, each slit SL may have a narrow portion whose width is less than that of the wide portion Ps1 in the outer circumferential portion OP.

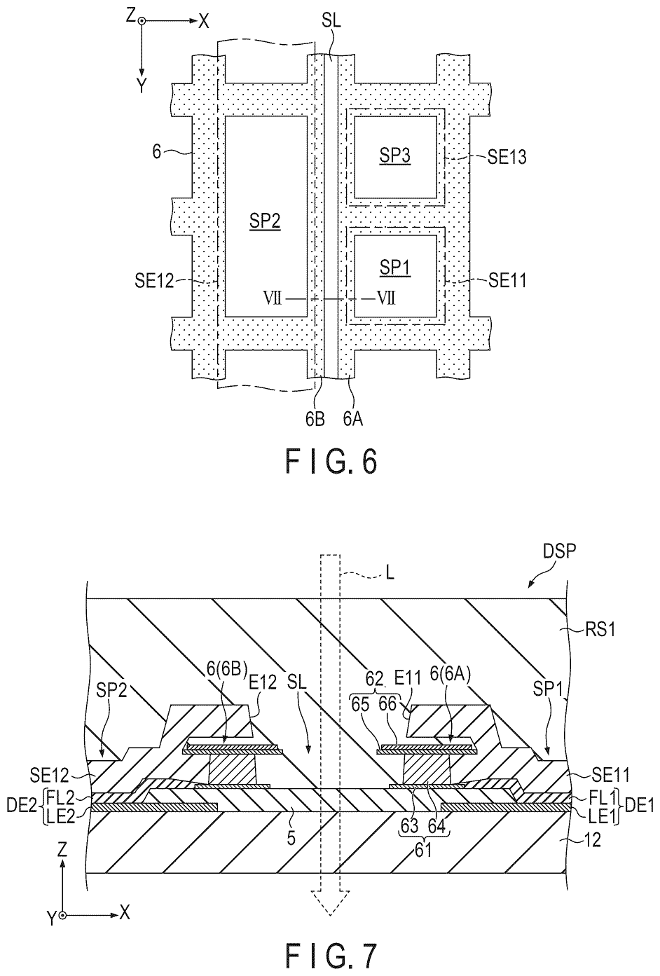

FIG. 6 is a schematic plan view showing an example of the relationship between the sealing layers SE11, SE12 and SE13 and the slit SL. The sealing layers SE11 and SE13 are formed into an island-like shape in subpixels SP1 and SP3, respectively. The sealing layer SE12 is, for example, continuously formed over the subpixels SP2 arranged in the Y-direction. As another example, the sealing layer SE12 may be formed for each subpixel SP2.

The end portions of the sealing layers SE11, SE12 and SE13 are located on the partition 6 as a whole. In the example of FIG. 6, none of the sealing layers SE11, SE12 and SE13 overlaps the slit SL. It should be noted that at least one of the sealing layers SE11, SE12 and SE13 may overlap the slit SL.

The slit SL passes through the area located between the sealing layer SE11 and the sealing layer SE12 and between the sealing layer SE13 and the sealing layer SE12 and extends in the Y-direction. In the partition 6, the portion in which the slit SL is provided is divided into partitions 6A and 6B by the slit SL.

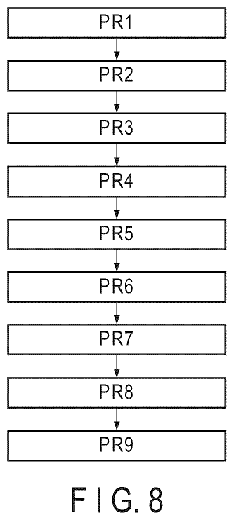

FIG. 7 is the schematic cross-sectional view of the display device DSP along the VII-VII line of FIG. 6. In this figure, the elements located under the organic insulating layer 12 and the elements located above the resin layer RS1 are omitted.

As shown in FIG. 7, each of the partitions 6A and 6B has an overhang shape in which the both end portions of the upper portion 62 protrude relative to the side surfaces of the lower portion 61 (the side surfaces of the stem layer 64). In addition, in the example of FIG. 7, in the slit SL, similarly, the end portion of the bottom layer 63 of each of the partitions 6A and 6B protrudes from the side surface of the stem layer 64.

An end portion E11 of the sealing layer SE11 is located above the partition 6A. An end portion E12 of the sealing layer SE12 is located above the partition 6B. The sealing layer SE11 continuously covers the display element DE1 of subpixel SP1 and part of the partition 6A. The sealing layer SE12 continuously covers the display element DE2 of subpixel SP2 and part of the partition 6B.

For example, the rib layer 5 is not open in the slit SL. In this case, the slit SL overlaps the rib layer 5 as a whole. For example, the slit SL is filled with the resin layer RS1. The resin layer RS1 covers the rib layer 5 in the slit SL.

None of the lower electrodes LE1, LE2 and LE3 overlaps the slit SL. For this reason, external light L which enters the slit SL passes through the slit SL to the lower side without being blocked by the partition 6 or the lower electrode LE1, LE2 or LE3.

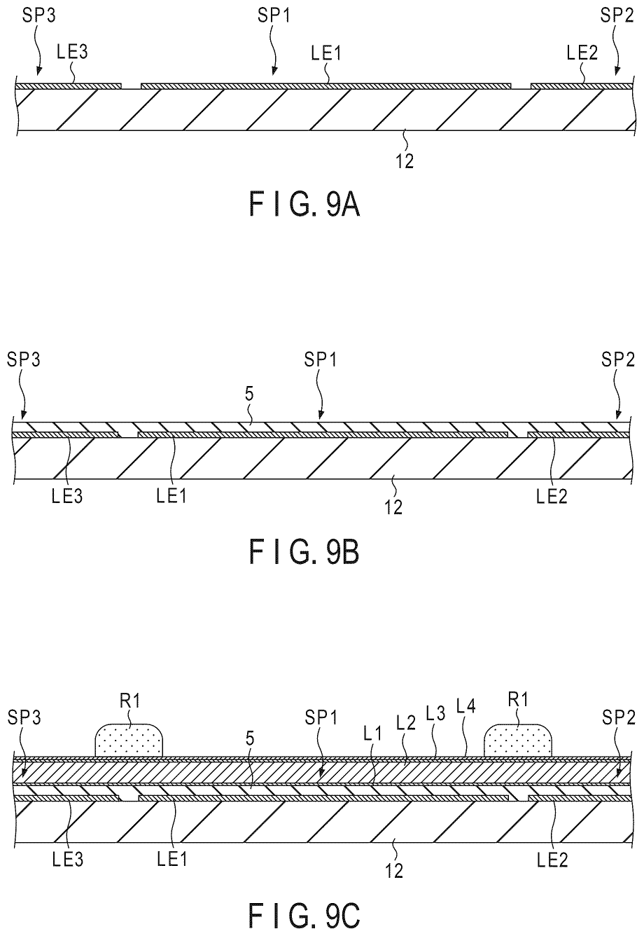

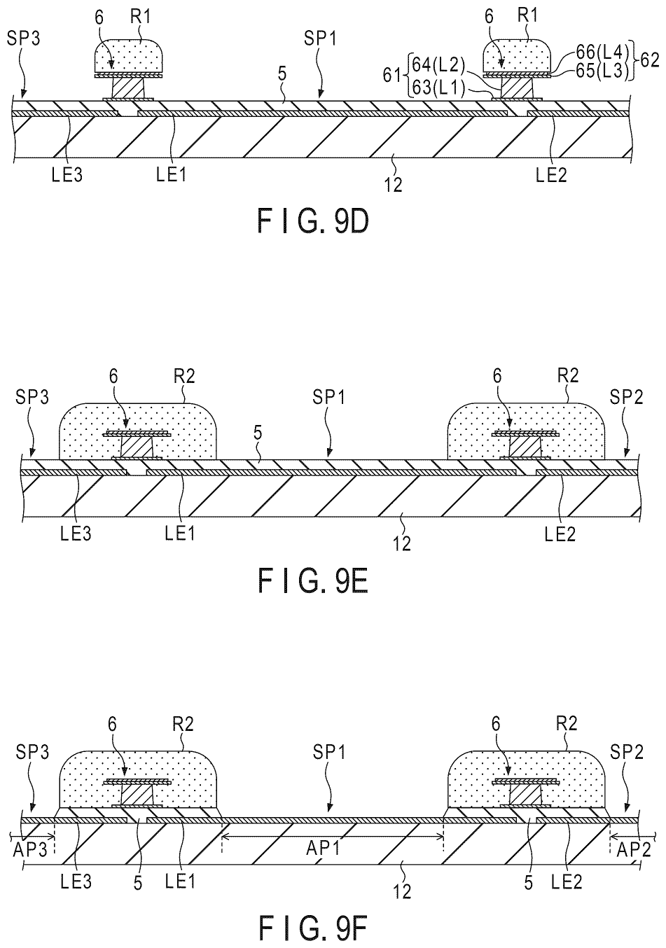

Now, this specification explains an example of the manufacturing method of the display device DSP. FIG. 8 is a flowchart showing an example of the manufacturing method of the display device DSP. Each of FIG. 9A to FIG. 9J is a schematic cross-sectional view showing the manufacturing process of the display device DSP. In FIG. 9A to FIG. 9J, the display area DA is mainly looked at, and the elements located under the organic insulating layer 12 are omitted.

To form the display device DSP, first, the circuit layer 11 and the organic insulating layer 12 are formed on the substrate 10 (process PR1 in FIG. 8). Subsequently, as shown in FIG. 9A, the lower electrodes LE1, LE2 and LE3 are formed on the organic insulating layer 12 (process PR2 in FIG. 8).

Subsequently, as shown in FIG. 9B, the rib layer 5 which covers the lower electrodes LE1, LE2 and LE3 is formed (process PR3 in FIG. 8). At this time, the pixel aperture AP1, AP2 or AP3 is not provided in the rib layer 5. The rib layer 5 may be formed by chemical vapor deposition (CVD).

After the formation of the rib layer 5, a process for forming the partition 6 is performed (process PR4 in FIG. 8). In process PR4, as shown in FIG. 9C, a first layer L1 which is processed so as to be the bottom layer 63, a second layer L2 which is processed so as to be the stem layer 64, a third layer L3 which is processed so as to be the first top layer 65 and a fourth layer L4 which is processed so as to be the second top layer 66 are formed in order. Further, a resist R1 is provided on the fourth layer L4. The resist R1 has been patterned into the shape of the partition 6. The first layer L1, the second layer L2, the third layer L3 and the fourth layer L4 are formed by, for example, sputtering.

Subsequently, the first layer L1, the second layer L2, the third layer L3 and the fourth layer L4 are patterned using the resist R1 as a mask. For example, the first layer L1 is formed of titanium nitride. The second layer L2 is formed of aluminum. The third layer L3 is formed of titanium. The fourth layer L4 is formed of ITO. In this case, the above patterning may include wet etching for removing the portion of the fourth layer L4 exposed from the resist R1, dry etching for removing the portions of the first, second and third layers L1, L2 and L3 exposed from the resist R1, and wet etching for reducing the width of the second layer L2.

Through process PR4, as shown in FIG. 9D, the partition 6 is formed in the display area DA. It should be noted that the slits SL described above are also formed by the above patterning. After the formation of the partition 6, the resist R1 is removed (peeled off). In the above wet etching for reducing the width of the second layer L2, the second top layer 66 (fourth layer L4) could be also slightly corroded. When this corrosion occurs, the width of the second top layer 66 becomes less than that of the first top layer 65.

Subsequently, a process for providing the pixel apertures AP1, AP2 and AP3 is performed (process PR5 in FIG. 8). In this process PR5, as shown in FIG. 9E, a resist R2 which covers the partition 6 is formed. Further, dry etching for the rib layer 5 is performed using the resist R2 as a mask. By this process, as shown in FIG. 9F, the pixel apertures AP1, AP2 and AP3 from which the lower electrodes LE1, LE2 and LE3 are exposed are formed in the rib layer 5. After the dry etching described above, the resist R2 is removed (peeled off).

After process PR5, a process for forming the display element DE1 is performed (process PR6 in FIG. 8). To form the display element DE1, first, as shown in FIG. 9G, the stacked film FL1 and the sealing layer SE11 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 may be formed by, for example, vapor deposition. The sealing layer SE11 may be formed by, for example, CVD.

The stacked film FL1 and the sealing layer SE11 are formed in the surrounding area SA as well as the display area DA. The stacked film FL1 is divided into a plurality of portions by the partition 6 having an overhang shape. The sealing layer SE11 continuously covers the portions into which the stacked film FL1 is divided, and the partition 6.

Subsequently, the stacked film FL1 and the sealing layer SE11 are patterned. In this patterning, as shown in FIG. 9G, a resist R3 is provided on the sealing layer SE11. The resist R3 covers subpixel SP1 and part of the partition 6 around subpixel SP1.

Subsequently, an etching process using the resist R3 a mask is performed. By this process, as shown in FIG. 9H, the portions of the stacked film FL1 and the sealing layer SE11 exposed from the resist R3 are removed. By this process, the display element DE1 is formed in subpixel SP1. This etching process includes wet etching and dry etching processes which are performed in order for the sealing layer SE11, the cap layer CP1, the upper electrode UE1 and the organic layer OR1. After these etching processes, the resist R3 is removed (peeled off).

It should be noted that the stacked film FL1 located under the sealing layer SE11 on the partition 6 is also removed in wet etching for the stacked film FL1. By this process, a gap is formed between the sealing layer SE11 located above the partition 6 and the partition 6. Since the stacked film FL1 which constitutes the display element DE1 is completely surrounded by the sealing layer SE11 and the partition 6, this stacked film FL1 is not corroded by the wet etching described above.

After process PR6, a process for forming the display element DE2 is performed (process PR7 in FIG. 8). The display element DE2 can be formed by a procedure similar to that of the display element DE1. Specifically, to form the display element DE2, the stacked film FL2 and the sealing layer SE12 are formed in the entire display area DA and surrounding area SA. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 may be formed by, for example, vapor deposition. The sealing layer SE12 may be formed by, for example, CVD. The stacked film FL2 is divided into a plurality of portions by the partition 6 having an overhang shape. The sealing layer SE12 continuously covers the portions into which the stacked film FL2 is divided, and the partition 6. By patterning these stacked film FL2 and sealing layer SE2, the display element DE2 is formed in subpixel SP2 as shown in FIG. 9I.

After process PR7, a process for forming the display element DE3 is performed (process PR8 in FIG. 8). The display element DE3 can be formed by a procedure similar to the procedures of the display elements DE1 and DE2. Specifically, to form the display element DE3, the stacked film FL3 and the sealing layer SE13 are formed in the entire display area DA and surrounding area SA. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 may be formed by, for example, vapor deposition. The sealing layer SE13 may be formed by, for example, CVD. The stacked film FL3 is divided into a plurality of portions by the partition 6 having an overhang shape. The sealing layer SE13 continuously covers the portions into which the stacked film FL3 is divided, and the partition 6. By patterning these stacked film FL3 and sealing layer SE13, the display element DE3 is formed in subpixel SP3 as shown in FIG. 9J.

After process PR8, the resin layer RS1, the sealing layer SE2 and the resin layer RS2 are formed in order (process PR9 in FIG. 8). To form the resin layers RS1 and RS2, for example, an ink-jet method may be used. To form the sealing layer SE2, for example, CVD may be used.

Now, this specification explains some effects obtained from the display device DSP according to the embodiment.

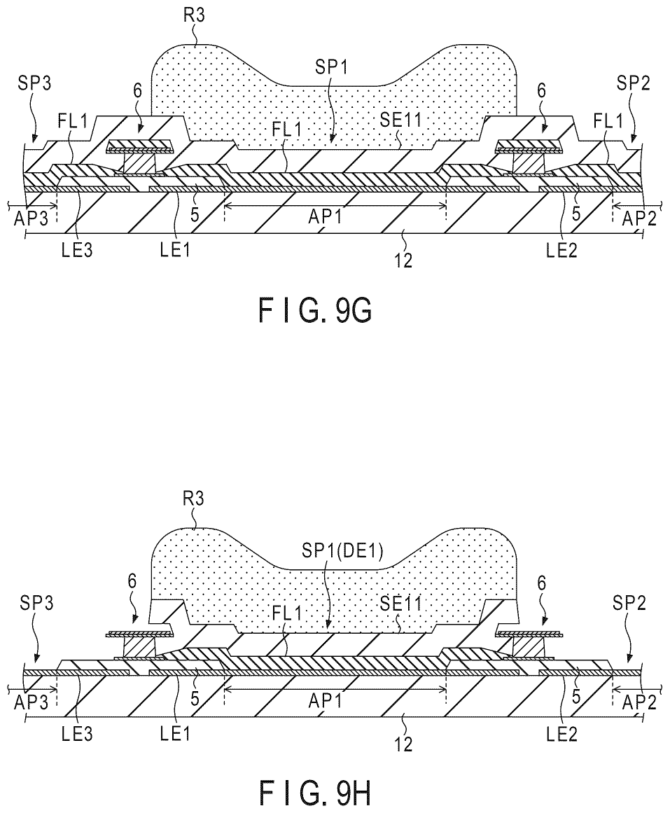

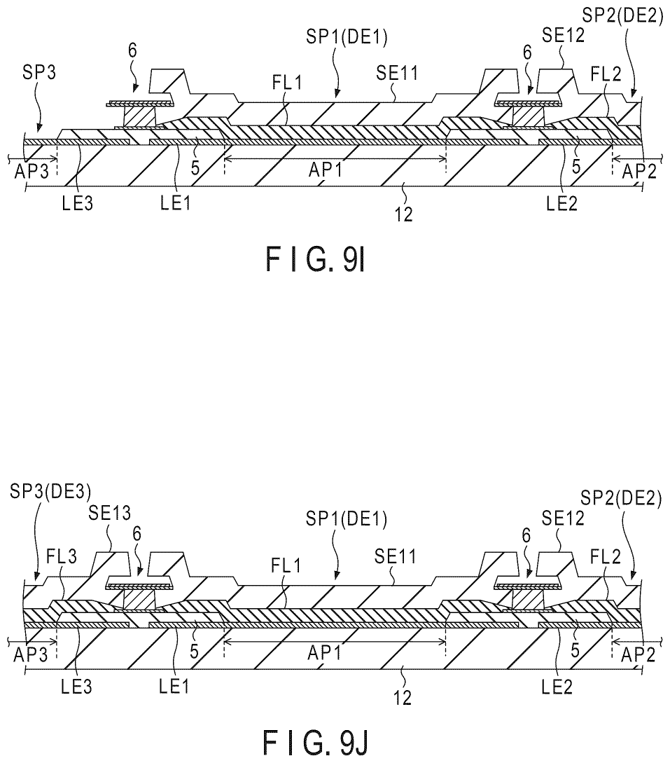

FIG. 10 and FIG. 11 are diagrams for explaining the effects of the display device DSP according to the embodiment. An electronic device on which the display device DSP is mounted may comprise an antenna AT1 for near field communication (NFC). The antenna AT1 is provided so as to, for example, face the rear side of the display device DSP (in other words, the lower surface of the substrate 10 shown in FIG. 3) and wirelessly communicates with the antenna AT2 of another electronic device through the display device DSP.

At the time of wireless communication between the antennas AT1 and AT2, eddy current I is generated in the common electrode CE by magnetic field M1 formed by the antenna AT1. By eddy current I, magnetic field M2 which negates magnetic field M1 is formed, and the signal strength is attenuated. Thus, when wireless communication is performed via the display device DSP, the communication sensitivity could be decreased. In particular, when the partition 6 mainly formed of a metal material and having a grating shape is formed in the entire display area DA, the resistance of the common electrode CE is low. Thus, a large eddy current I occurs, thereby generating a strong magnetic field M2. Thus, the communication sensitivity is easily decreased.

To the contrary, in the embodiment, the common electrode CE is divided into a plurality of segments SG by the slits SL. In this case, a large eddy current is not easily generated in the common electrode CE. Thus, the decrease in communication sensitivity can be prevented. Eddy current could be generated in each segment SG. However, the effect caused to communication sensitivity by this eddy current is tiny compared to eddy current I generated in the entire part of a common electrode CE which is not divided.

Electronic devices on which the display device DSP is mounted may comprise an optical sensor such as an illumination sensor which detects external light. When such an optical sensor is provided on the rear side of the display device DSP, translucency is required in the display device DSP.

However, each of the lower electrodes LE1, LE2 and LE3 includes the reflective layer described above. In addition, the partition 6 which is at least partly formed of a metal material has light-shielding properties. For this reason, the light which is made incident on the display surface of the display device DSP could be mostly reflected or blocked without being transmitted to the rear side.

To the contrary, when the slits SL are provided in the partition 6 like the embodiment, as in the case of external light L shown in FIG. 7, part of the light which is made incident on the display surface is transmitted to the rear side of the display device DSP through the slits SL. By this configuration, the translucency of the display device DSP can be enhanced.

In this manner, the embodiment can provide the display device DSP which is compatible with an antenna for wireless communication and an optical sensor. Moreover, as explained below, the embodiment can improve the yield of the display device DSP.

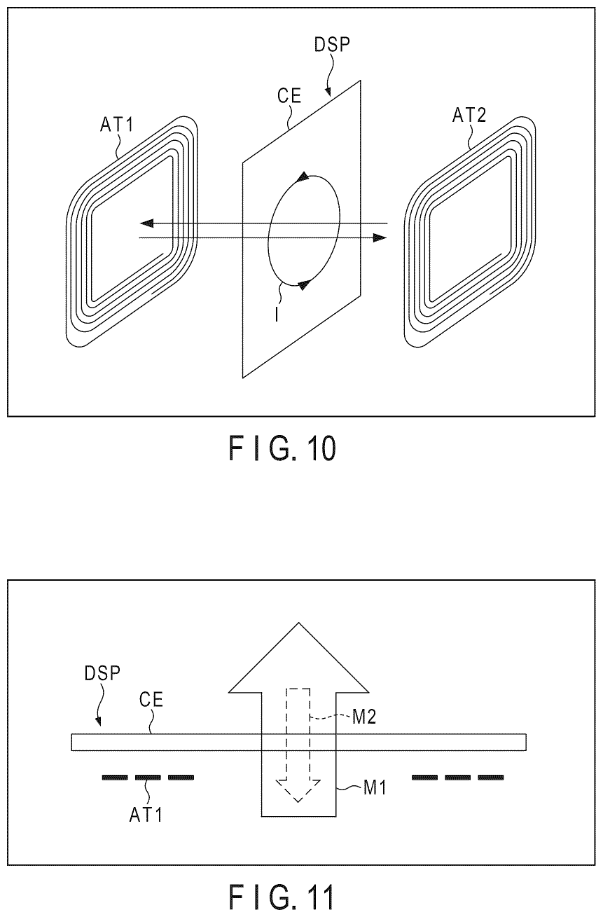

FIG. 12 is the schematic cross-sectional view of the display device DSP immediately after the display element DE1 is formed. The section of this figure shows a portion similar to that of FIG. 7 and includes subpixel SP1, the partitions 6A and 6B and the slit SL.

As shown in FIG. 12, a large step having a complicated shape is formed near the slit SL by the end portion E11 of the sealing layer SE11 and the partition 6A. By this configuration, an air bubble is easily generated inside the slit SL in the manufacturing process of the display device DSP.

If process PR7 for forming the display element DE2 is performed in a state where an air bubble is generated, the air bubble bursts at the time of the reduced-pressure drying of the resist for patterning the stacked film FL2 and the sealing layer SE12. Thus, the area which should be covered with the resist under normal conditions is exposed. A similar situation may occur in the subsequent process PR8.

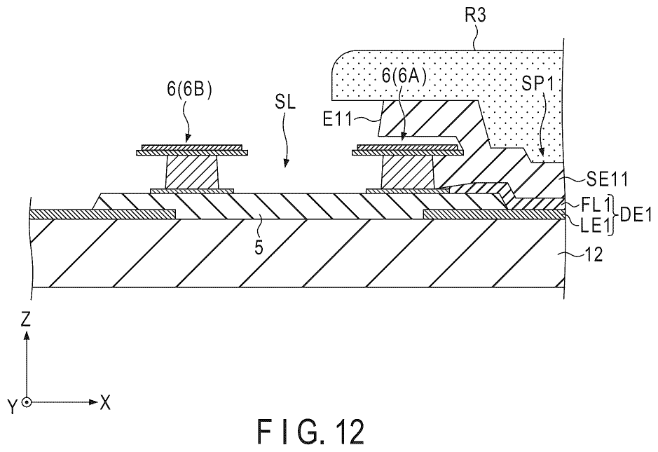

FIG. 13 is a schematic plan view of the partition 6 according to a comparative example of the embodiment. In this figure, in a manner similar to that of FIG. 5, the vicinity of the first end portion Ea of each segment SG is particularly looked at. In this comparative example, each slit SL does not reach the outer circumferential portion OP.

The phenomenon in which a resist bursts as described above easily occurs near the first end portions Ea like positions Q shown by the chained circles in FIG. 13. For this reason, if the distance between the first end portions Ea and the display area DA is short, in other words, if the end portions of the slits SL are close to the display area DA, there is a possibility that the problems caused by the burst of the resist act on the display area DA.

To the contrary, in the present embodiment, the slits SL reach the outer circumferential portion OP as shown in FIG. 5. In this case, it is possible to assure a sufficient distance between the first end portions Ea of the segments (the end portions of the slits SL) and the display area DA. Therefore, even if a resist bursts near the end portions of the slits SL, the effect caused by the burst does not easily act on the display area DA. As a result, the yield of the display device DSP is improved. When length Ls of each slit SL in the outer circumferential portion OP is greater than or equal to width Wy of each pixel PX, this effect can be further enhanced.

In addition, in this embodiment, the width of each slit SL is increased in the outer circumferential portion OP. In this case, an air bubble to be the cause of the burst of a resist is not easily generated near the end portions of the slits SL.

Various desirable effects can be obtained from the present embodiment other than the above description.

### Second Embodiment

A second embodiment is explained. With regard to configurations which are not particularly referred to in this embodiment, configurations similar to those of the first embodiment can be applied.

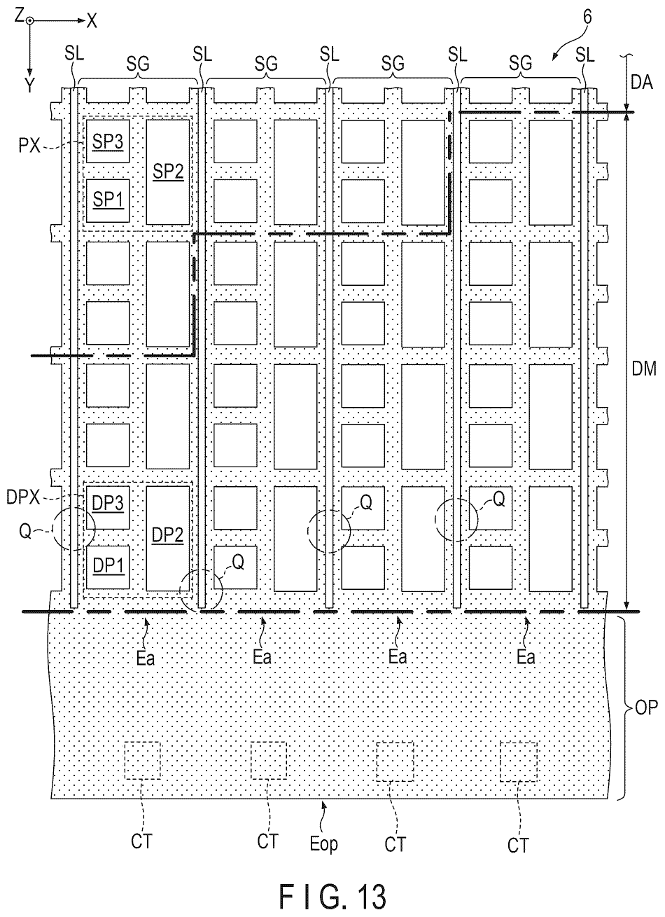

FIG. 14 is a schematic plan view showing a configuration according to the second embodiment. In this figure, in a manner similar to that of FIG. 5, the vicinity of the first end portion Ea of each segment SG is particularly looked at.

In the example of FIG. 14, the end portion of each slit SL is located near the outer edge EoP of an outer circumferential portion OP compared with the example of FIG. 5. By this configuration, length Ls of each slit SL in the outer circumferential portion OP is also increased. For example, length Ls is twice width Wy of each pixel PX in a Y-direction or greater (Ls≥2×Wy).

In a manner similar to that of the first embodiment, each slit SL has a wide portion Ps1. Further, each slit SL has a narrow portion Ps2 in the outer circumferential portion OP. Each narrow portion Ps2 is located between the wide portion Ps1 and a dummy pixel area DM.

Each narrow portion Ps2 has width Ws3 which is less than width Ws2 of each wide portion Ps1 (Ws2>Ws3). For example, width Ws3 is equal to width Ws1. As another example, width Ws3 may be greater than width Ws1 and less than width Ws2. The length of each wide portion Ps1 or each narrow portion Ps2 in the Y-direction is not particularly limited. For example, these lengths are equal to each other.

By increasing length Ls of each slit SL in the outer circumferential portion OP like the present embodiment, the position at which a resist may burst as described above can be made more distant from a display area DA.

### Third Embodiment

A third embodiment is explained. With regard to configurations which are not particularly referred to in this embodiment, configurations similar to those of each of the embodiments described above can be applied.

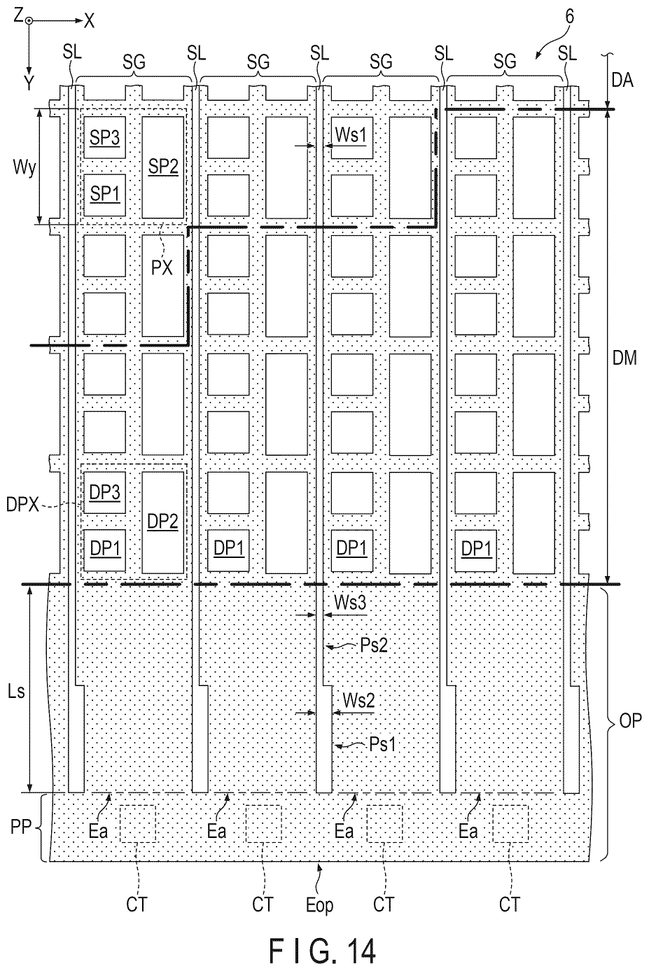

FIG. 15 is a schematic plan view showing a configuration according to the third embodiment. In this figure, in a manner similar to that of FIG. 5, the vicinity of the first end portion Ea of each segment SG is particularly looked at. In a manner similar to that of FIG. 14, each slit SL has a wide portion Ps1 and a narrow portion Ps2.

In the example of FIG. 15, each slit SL (wide portion Ps1) reaches the outer edge EoP of an outer circumferential portion OP. Each segment SG is connected to the power supply line PW shown in FIG. 4 via a contact portion CT.

If each slit SL reaches the outer edge EoP like the present embodiment, even in a case where the air bubble described above is generated, the air bubble easily goes out of the aperture portion of the slit SL at the outer edge EoP. By this configuration, the phenomenon in which a resist bursts can be further satisfactorily prevented.

### Fourth Embodiment

A fourth embodiment is explained. With regard to configurations which are not particularly referred to in this embodiment, configurations similar to those of each of the embodiments described above can be applied.

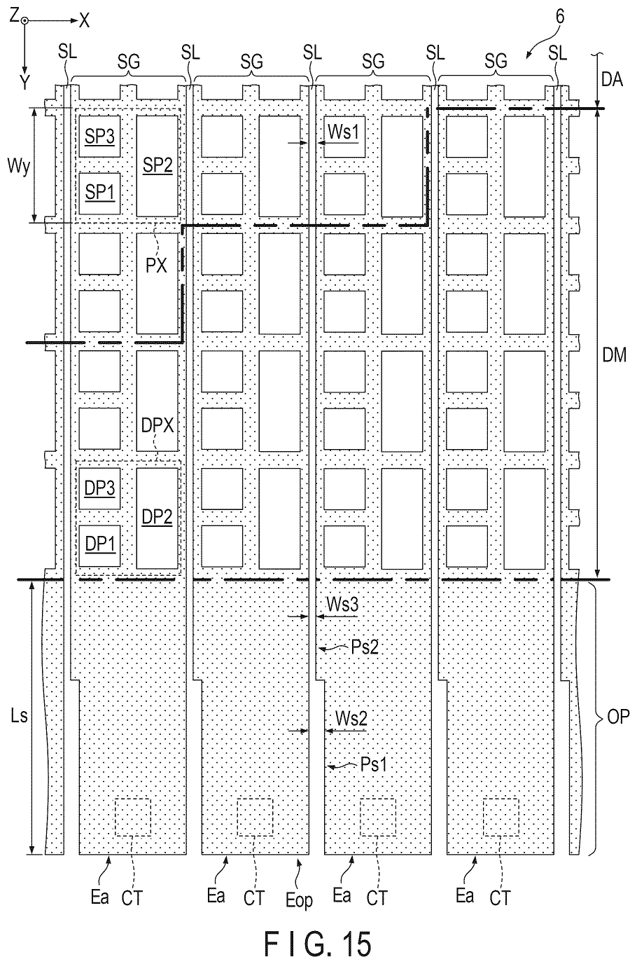

FIG. 16 is a schematic plan view showing a configuration according to the fourth embodiment. In this figure, in a manner similar to that of FIG. 5, the vicinity of the first end portion Ea of each segment SG is particularly looked at. In the example of FIG. 16, a partition 6 includes a plurality of connection portions CN each of which intersects with a slit SL and connects segments SG which are adjacent to each other. The other configurations are similar to those of the example of FIG. 5. It should be noted that similar connection portions CN may be provided in the configurations of FIG. 14 and FIG. 15.

For example, each connection portion CN is provided at a position adjacent to subpixel SP3 or dummy subpixel DP3 in an X-direction. By providing these connection portions CN, the resistance of the partition 6 can be reduced.

It should be noted that, if the connection portions CN are provided in all of the slits SL, the effect of preventing the eddy current described above is reduced. Therefore, it is preferable that a slit SL in which no connection portion CN is provided should be present like the slit SL located at the right end in FIG. 16.

### Fifth Embodiment

A fifth embodiment is explained. With regard to configurations which are not particularly referred to in this embodiment, configurations similar to those of each of the embodiments described above can be applied.

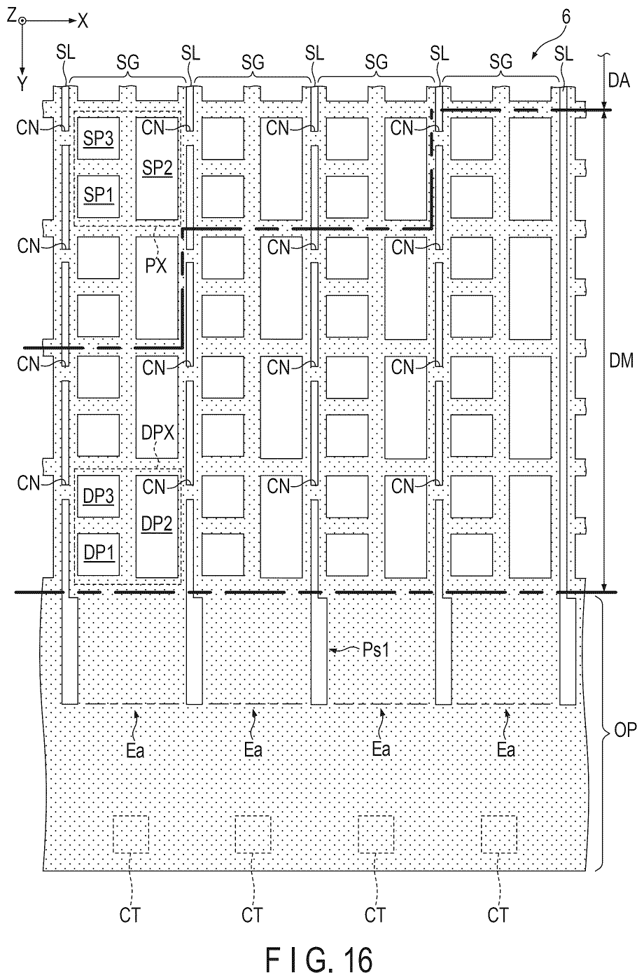

FIG. 17 is a schematic plan view showing a configuration according to the fifth embodiment. This figure shows a partition 6, sealing layers SE11, SE12 and SE13 and a slit SL in a manner similar to that of FIG. 6. A diagonal pattern is added to the sealing layer SE11.

In the example of FIG. 17, the sealing layer SE11 covers subpixel SP1 and also overlaps the slit SL. Specifically, the sealing layer SE11 is a rectangle which is elongated in an X-direction, and intersects with the slit SL as seen in plan view. A similar configuration can be applied to the sealing layer SE11 of dummy subpixel DP1. It should be noted that some sealing layers SE11 provided in a display area DA and a dummy pixel area DM may not overlap the slits SL.

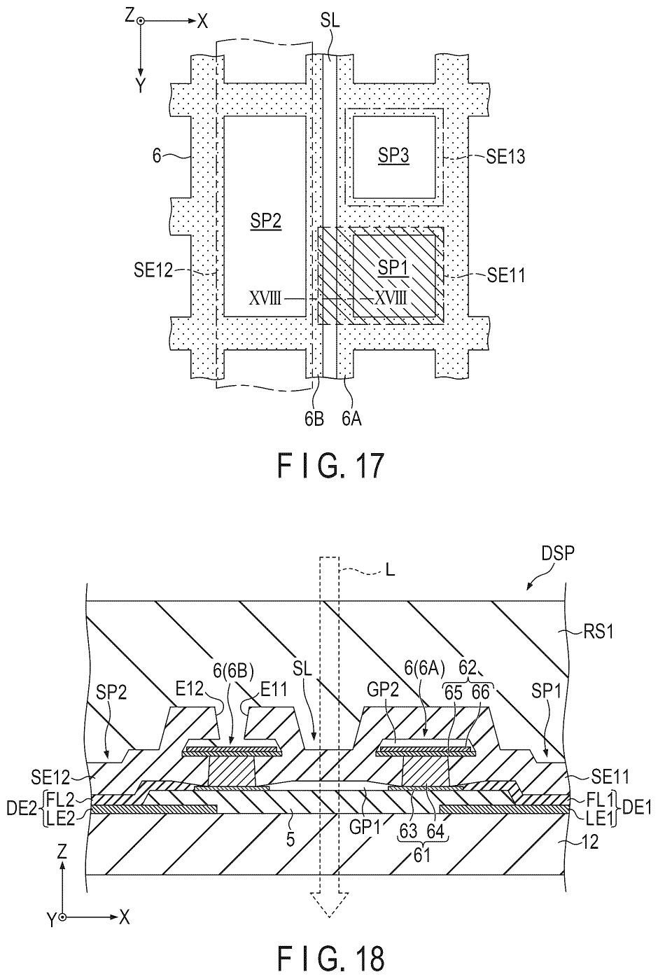

FIG. 18 is the schematic cross-sectional view of a display device DSP along the XVIII-XVIII line of FIG. 17. In this figure, the elements located under an organic insulating layer 12 and the elements located above a resin layer RS1 are omitted.

In the section of FIG. 18, the sealing layer SE11 continuously covers the display element DE1 of subpixel SP1, a partition 6A and the slit SL. Further, the sealing layer SE11 is partly located inside the slit SL. In other words, at least part of the slit SL is filled with the sealing layer SE11.

An end portion E11 of the sealing layer SE11 is located above a partition 6B. An end portion E12 of the sealing layer SE12 of subpixel SP2 is also located above the partition 6B. These end portions E11 and E12 are spaced apart from each other in the X-direction.

In the example of FIG. 18, a gap GP1 is formed under the sealing layer SE11 which covers the slit SL. The gap GP1 corresponds to a void located between the upper surface of a rib layer 5 and the lower surface of the sealing layer SE11. A gap GP2 is formed under the sealing layer SE11 above the partition 6A. The gap GP2 corresponds to a void located between the upper portion 62 of the partition 6A and the lower surface of the sealing layer SE11. A stacked film FL1 may be present in part of these gaps GP1 and GP2. The manufacturing method of the display

device DSP in this embodiment is similar to that explained in the first embodiment. In process PR6 for forming the display element DE1, before wet etching for the stacked film FL1, the stacked film FL1 is formed in portions corresponding to the gaps GP1 and GP2. The stacked film FL1 in these portions is removed as the etchant penetrates from the vicinity of the end portion of the sealing layer SE11 to the lower side of the sealing layer SE11 in the wet etching. Thus, the gaps GP1 and GP2 are formed.

When the sealing layer SE11 covers the slit SL near subpixel SP1 like this embodiment, the step of the vicinity of the slit SL and the complicated shape formed by the partitions 6A and 6B are eased. Air bubbles are not easily generated in the slit SL. This configuration can prevent the phenomenon in which the resists formed in processes PR7 and PR8 burst in the display area DA and the dummy pixel area DM.

When the stacked film FL1 is formed under the sealing layer SE11 in the slit SL, the partitions 6A and 6B may be electrically continuous with each other by an upper electrode UE1. In this case, the prevention of the eddy current described above is disturbed. In addition, the transmittance of the slit SL may be reduced by the stacked film FL1. To the contrary, when the stacked film FL1 located under the sealing layer SE11 is removed by the etching of the stacked film FL1 as described above, the conduction of the segments SG which are adjacent to each other via the slit SL is prevented, and further, the transmittance in the slit SL can be increased.

### Sixth Embodiment

A sixth embodiment is explained. With regard to configurations which are not particularly referred to in this embodiment, configurations similar to those of each of the embodiments described above can be applied.

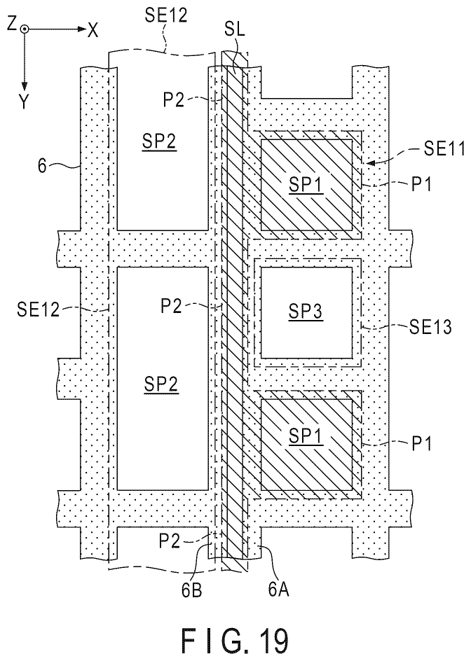

FIG. 19 is a schematic plan view showing a configuration according to the sixth embodiment. This figure shows a partition 6, sealing layers SE11, SE12 and SE13 and a slit SL in a manner similar to that of FIG. 6. A diagonal pattern is added to the sealing layer SE11.

In the example of FIG. 19, the sealing layer SE11 includes a plurality of first portions P1 which overlap subpixels SP1, and a second portion P2 which connects these first portions P1. The second portion P2 overlaps a slit SL, passes through the area located between the sealing layers SE12 and SE13 and extends in a Y-direction (the extension direction of the slit SL).

When the sealing layer SE11 has this shape, the slit SL is covered with the sealing layer SE11 as a whole. This configuration more effectively prevents the generation of the air bubbles described above.

When the slit SL is covered with the sealing layer SE11 as a whole, a stacked film FL1 may remain inside the slit SL, and thus, the segments SG which are adjacent to each other may be electrically continuous with each other by an upper electrode UE1 included in the stacked film FL1. Thus, if all of the slits SL provided in a display area DA have the same structure as the slit SL shown in FIG. 19, there is a possibility that the effect of preventing the eddy current described above is reduced.

Therefore, it is preferable that a slit SL which is not covered with the sealing layer SE11 at all as shown in FIG. 6 and a slit SL which includes a portion which is not covered with the sealing layer SE11 as shown in FIG. 17 should be present. For example, these slits SL and the slit SL shown in FIG. 19 may be alternately provided in an X-direction.

### Seventh Embodiment

A seventh embodiment is explained. With regard to configurations which are not particularly referred to in this embodiment, configurations similar to those of each of the embodiments described above can be applied.

The first embodiment assumes a case where display elements DE1, DE2 and DE3 are formed in this order. The seventh embodiment assumes a case where the display element DE2 is formed firstly, and the display elements DE1 and DE3 are subsequently formed. In this case, resists may burst as described above when the display elements DE1 and DE3 are formed. For this reason, as exemplarily described below, at least part of a slit SL should be preferably filled with a sealing layer SE12.

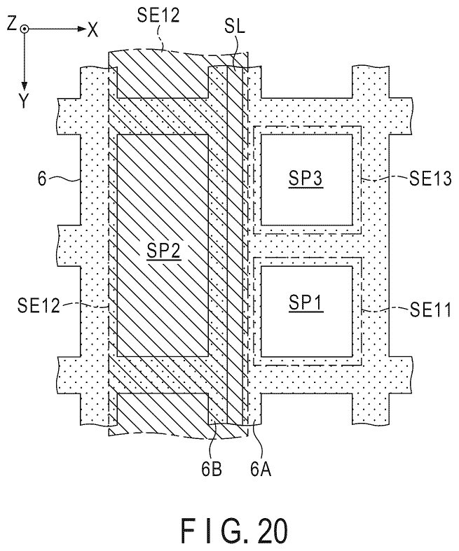

FIG. 20 is a schematic plan view showing a configuration according to the seventh embodiment. This figure shows a partition 6, sealing layers SE11, SE12 and SE13 and the slit SL in a manner similar to that of FIG. 6. A diagonal pattern is added to the sealing layer SE12.

The sealing layer SE12 shown in FIG. 20 has a belt-like shape which continuously covers subpixels SP2 arranged in a Y-direction. Further, the sealing layer SE12 covers the slit SL as a whole. This configuration effectively prevents the generation of the air bubbles described above.

In the slit SL overlapping the sealing layer SE12, a stacked film FL2 may be formed under the sealing layer SE12. In this case, adjacent segments SG may be electrically continuous with each other by an upper electrode UE2 included in the stacked film FL2. Thus, if all of the sealing layers SE12 in a display area DA have the shape shown in FIG. 20, there is a possibility that the effect of preventing the eddy current described above is reduced.

For this reason, it is preferable that a slit SL which is not covered with the sealing layer SE11 at all as shown in FIG. 6 should be present. For example, such a slit SL and the slit SL shown in FIG. 20 may be alternately provided in an X-direction.

It should be noted that, when the display element DE3 is formed firstly, the sealing layer SE13 may be provided in the same form as the sealing layers SE11 exemplarily shown in FIG. 17 and FIG. 19. This configuration can prevent the phenomenon in which resists may burst when the display elements DE1 and DE2 are formed as described above.

All of the display devices that can be implemented by a person of ordinary skill in the art through arbitrary design changes to the display device described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a display area which includes a plurality of pixels;
a plurality of display elements which are provided in the pixels, respectively, and each of which includes an organic layer which emits light based on application of voltage;
a dummy pixel area which includes a plurality of dummy pixels and is located outside the display area; and
a partition which includes a conductive lower portion and an upper portion having an end portion protruding from a side surface of the lower portion and surrounds each of the pixels and the dummy pixels, wherein
the partition has an outer circumferential portion located outside the dummy pixel area, and is divided into a plurality of segments by a slit which passes through the display area and the dummy pixel area and which reaches the outer circumferential portion.

2. The display device of claim 1, wherein
a length of the slit in the outer circumferential portion is greater than or equal to a width of the pixel in an extension direction of the slit.

3. The display device of claim 2, wherein
the length of the slit in the outer circumferential portion is twice the width of the pixel in the extension direction or greater.

4. The display device of claim 1, wherein
the slit has a first width in the display area, and has a second width greater than the first width in at least part of the outer circumferential portion.

5. The display device of claim 4, wherein
the slit includes:
a wide portion which is located in the outer circumferential portion and has the second width; and
a narrow portion which is located between the wide portion and the dummy pixel area in the outer circumferential portion and has a third width less than the second width.

6. The display device of claim 5, wherein
the third width is equal to the first width.

7. The display device of claim 1, wherein
the partition further includes a connection portion which intersects with the slit and which connects the segments.

8. The display device of claim 1, wherein
at least an end of the slit reaches an outer edge of the outer circumferential portion.

9. The display device of claim 8, wherein
both ends of the slit reach the outer edge of the outer circumferential portion.

10. The display device of claim 1, further comprising a plurality of sealing layers which are formed of an inorganic insulating material and cover the display elements, respectively, wherein
at least one of the sealing layers overlaps at least part of the slit as seen in plan view.

11. The display device of claim 10, wherein
at least one of the sealing layers intersects with the slit as seen in plan view.

12. The display device of claim 10, wherein
at least one of the sealing layers includes a portion covering the slit and extending in an extension direction of the slit.

13. A display device comprising:
a display area which includes a plurality of pixels;
a plurality of display elements which are provided in the pixels, respectively, and each of which includes an organic layer which emits light based on application of voltage; and
a partition which includes a conductive lower portion and an upper portion having an end portion protruding from a side surface of the lower portion, and surrounds each of the pixels, wherein
the partition has an outer circumferential portion located outside the display area, and is divided into a plurality of segments by a slit which passes through the display area and which reaches the outer circumferential portion, and
the slit has a first width in the display area, and has a second width greater than the first width in at least part of the outer circumferential portion.

14. The display device of claim 13, wherein
the slit includes:
a wide portion which is located in the outer circumferential portion and has the second width; and
a narrow portion which is located between the wide portion and the display area in the outer circumferential portion and has a third width less than the second width.

15. The display device of claim 14, wherein
the third width is equal to the first width.

16. The display device of claim 13, wherein
a length of the slit in the outer circumferential portion is greater than or equal to a width of the pixel in an extension direction of the slit.

17. The display device of claim 16, wherein
the length of the slit in the outer circumferential portion is twice the width of the pixel in the extension direction or greater.

18. The display device of claim 13, wherein
the partition further includes a connection portion which intersects with the slit and which connects the segments.

19. The display device of claim 13, wherein
at least an end of the slit reaches an outer edge of the outer circumferential portion.

20. The display device of claim 19, wherein
both ends of the slit reaches the outer edge of the outer circumferential portion.
